(19) United States
(12) Patent Application Publication
(10) Pub. No.: US 2024/0212317 A1
(43) Pub. Date: Jun. 27, 2024

(54) HIERARCHICAL CLUSTERING OF FOURIER TRANSFORM BASED LAYOUT PATTERNS

(71) Applicant: ASML Netherlands B.V., Veldhoven (NL)

(72) Inventors: Jingchun WANG, San Jose, CA (US); Chuang YE, San Jose, CA (US); Shengcheng JIN, San Jose, CA (US)

(73) Assignee: ASML Netherlands B.V., Veldhoven (NL)

(21) Appl. No.: 18/557,578

(22) PCT Filed: Apr. 28, 2022
(86) PCT No.: PCT/EP2022/061319

§ 371 Date: Oct. 26, 2023

Related U.S. Application Data
(60) Provisional application No. 63/181,902, filed on Apr. 29, 2021.

(51) Int. Cl. G06V 10/762; G06T 5/10; G06T 7/00; G06T 7/11; G06V 10/44; G06V 10/74

(52) U.S. Cl. CPC G06V 10/762; G06T 5/10; G06T 7/0004; G06T 7/11; G06V 10/44; G06V 10/761; G06T 2207/30148

(57) ABSTRACT

Apparatuses, systems, and methods for grouping a plurality of patterns extracted from image data are disclosed. In some embodiments, the method for grouping the patterns comprises receiving the image data including the plurality of patterns that represent features to be formed on a portion of a wafer. The method also comprises separating the plurality of patterns after Fourier Transform into multiple sets of patterns. The method further comprises performing, to a respective set of patterns, a hierarchical clustering to obtain a plurality of subsets of patterns by recursively evaluating features related to similarity between patterns within the respective set of patterns.

### TECHNICAL FIELD

The embodiments provided herein relate to a system and a method for clustering reference data (e.g., layout patterns, GDS patterns) of integrated circuits layout for facilitating mask inspection or wafer inspection.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important.

A charged particle (e.g., electron) beam microscope, such as a scanning electron microscope (SEM) or a transmission electron microscope (TEM) can serve as a practicable tool for inspecting IC components. Critical dimensions of patterns or structures measured from SEM or TEM image can be used to detect defects of manufactured ICs. For example, shifts between patterns or edge placement variations can be helpful in controlling manufacturing processes as well as in determining defects.

### SUMMARY

Embodiments of the present disclosure provide apparatuses, systems, and methods for grouping reference data.

In some embodiments, a method for grouping a plurality of patterns extracted from image data is provided. The method comprises receiving the image data including the plurality of patterns that represent features to be formed on a portion of a wafer; separating the plurality of patterns after Fourier Transform into multiple sets of patterns; and performing, on a respective set of patterns, a hierarchical clustering to obtain a plurality of subsets of patterns by recursively evaluating features related to similarity between patterns within the respective set of patterns.

In some embodiments, a system for grouping a plurality of patterns extracted from image data is provided. The system comprises a controller including circuitry configured to cause the system to perform receiving the image data including the plurality of patterns that represent features to be formed on a portion of a wafer; separating the plurality of patterns after Fourier Transform into multiple sets of patterns; and performing, on a respective set of patterns, a hierarchical clustering to obtain a plurality of subsets of patterns by recursively evaluating features related to similarity between patterns within the respective set of patterns.

In some embodiments, a non-transitory computer readable medium that stores a set of instructions that is executable by at least one processor of a system to cause the system to perform a method of grouping a plurality of patterns extracted from image data is provided. The method comprises receiving the image data including the plurality of patterns that represent features to be formed on a portion of a wafer; separating the plurality of patterns after Fourier Transform into multiple sets of patterns; and performing, on a respective set of patterns, a hierarchical clustering to obtain a plurality of subsets of patterns by recursively evaluating features related to similarity between patterns within the respective set of patterns.

In some embodiments, a method for grouping a plurality of patterns is provided. The method comprises receiving image data including the plurality of patterns that represent features to be formed on a portion of a wafer; performing a hierarchical clustering on a plurality of frequency domain features transformed from the plurality of patterns respectively, wherein performing the hierarchical clustering comprises recursively partitioning the plurality of frequency domain features by performing: receiving a user selection of a parameter; and recursively evaluating, based on the parameter, whether to continue to partition corresponding sets of patterns at respective hierarchical levels.

In some embodiments, a system for grouping a plurality of patterns extracted from image data is provided. The system comprises a controller including circuitry configured to cause the system to perform receiving image data including the plurality of patterns that represent features to be formed on a portion of a wafer; performing a hierarchical clustering on a plurality of frequency domain features transformed from the plurality of patterns respectively, wherein performing the hierarchical clustering comprises recursively partitioning the plurality of frequency domain features by performing: receiving a user selection of a parameter; and recursively evaluating, based on the parameter, whether to continue to partition corresponding sets of patterns at respective hierarchical levels.

In some embodiments, a non-transitory computer readable medium that stores a set of instructions that is executable by at least one processor of a system to cause the system to perform a method of grouping a plurality of patterns extracted from image data is provided. The method comprises receiving image data including the plurality of patterns that represent features to be formed on a portion of a wafer; performing a hierarchical clustering on a plurality of frequency domain features transformed from the plurality of patterns respectively, wherein performing the hierarchical clustering comprises recursively partitioning the plurality of frequency domain features by performing: receiving a user selection of a parameter; and recursively evaluating, based on the parameter, whether to continue to partition corresponding sets of patterns at respective hierarchical levels.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 illustrates a schematic diagram illustrating an example electron beam inspection (EBI) system, consistent with some embodiments of the present disclosure.

FIG. 2 illustrates a schematic diagram illustrating an example electron beam tool that can be a part of the electron beam inspection system of FIG. 1, consistent with some embodiments of the present disclosure.

FIG. 3 illustrates a block diagram of an example system for processing reference data, consistent with some embodiments of the present disclosure.

FIG. 4A illustrates an example process of a first-level grouping of patterns included in reference data, in accordance with some embodiments of the present disclosure.

FIG. 4B illustrates an example process of clustering patterns included in reference data, in accordance with some embodiments of the present disclosure.

FIG. 4C illustrates an example process of a second-level grouping of patterns included in reference data, in accordance with some embodiments of the present disclosure.

FIG. 4D illustrates an example diagram of comparing two patterns during a clustering or grouping process, in accordance with some embodiments of the present disclosure.

FIG. 5A illustrates an example process of performing Fourier Transform on a plurality of patterns in the reference data, in accordance with some embodiments of the present disclosure.

FIG. 5B illustrates an example process of converting Fourier Transform based reference images into vectors, in accordance with some embodiments of the present disclosure.

FIG. 5C illustrates a diagram showing an example hierarchical clustering process for partitioning the Fourier Transform based features, in accordance with some embodiments of the present disclosure.

FIG. 6A illustrates a diagram for a cohesion test, in accordance with some embodiments of the present disclosure.

FIG. 6B illustrates a diagram where the recursive partition continues, in accordance with some embodiments of the present disclosure.

FIG. 6C illustrates a diagram where the recursive partition stops, in accordance with some embodiments of the present disclosure.

FIG. 7 is a process flowchart representing an example method for processing reference data, in accordance with some embodiments of the present disclosure.

FIG. 8 is a process flowchart representing an example method for processing reference data, in accordance with some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step (e.g., in design or patterning) have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. Defects may be generated during various stages of semiconductor processing. Hotspots are areas with a higher likelihood of having defects after lithography patterning or etching. Therefore, it is important to identify and reduce hotspots early in the design stage, or to identify defects accurately and efficiently as early as possible.

During the wafer inspection process, areas of interest on the wafer may be determined. In some embodiments, areas of interest may include patterns with different shapes, such as polygons, squares, or any other regular or irregular shapes that are suitable for inspection. Various systems and processes for inspection may face challenges due to, for example, the massive number of features on an integrated circuit (IC), and the complexity of analyzing the massive data of the IC or of the SEM images of the IC. For example, pattern grouping or clustering process may be time consuming. Further, the grouping or clustering parameters, such as a number of groups or how similar the patterns can be within each group, are predefined and fixed. The user may not have control over how many groups the pattern can be classified, or a degree of similarity between patterns within a group.

Some of the disclosed embodiments provide systems and methods that address some or all of the disadvantages disclosed herein. In the present disclosure, IC data, or reference data (also referred to as reference image data, design data, standard data, layout data), such as graphic database system (GDS) data files, can be processed to group or cluster patterns with certain similar characteristic(s). In some embodiments, similar patterns may be grouped or clustered so that the inspection can be performed on a representative pattern of each group to improve the inspection efficiency. In some embodiments, the patterns are grouped based on geometric characteristics. In some embodiments, the patterns are processed to obtain high dimensional vectors in frequency domain, and the vectors are processed using hierarchical clustering to partition the whole dataset into a plurality of groups. Accordingly, hotspot analysis or wafer inspection can be performed with improved efficiency and accuracy. Furthermore, the user can adjust one or more parameters to customize the hierarchical clustering, so as

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

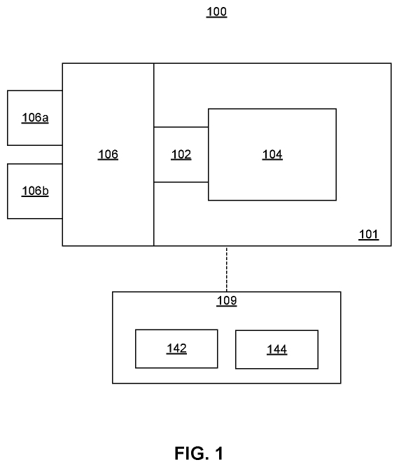

FIG. 1 illustrates an exemplary electron beam inspection (EBI) system 100 consistent with some embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system. It is appreciated that the system and method disclosed herein can apply to both single-beam system and multi-beam system.

A controller 109 is electronically connected to electron beam tool 104. Controller 109 may be a computer configured to execute various controls of EBI system 100. Controller 109 may also include processing circuitry configured to execute various signal and image processing functions. In some embodiments, controller 109 may be separate and independent from EBI system 100. For example, controller 109 may be a computer communicatively coupled to EBI system 100. In some embodiments, while controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors 142. A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories 144. A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

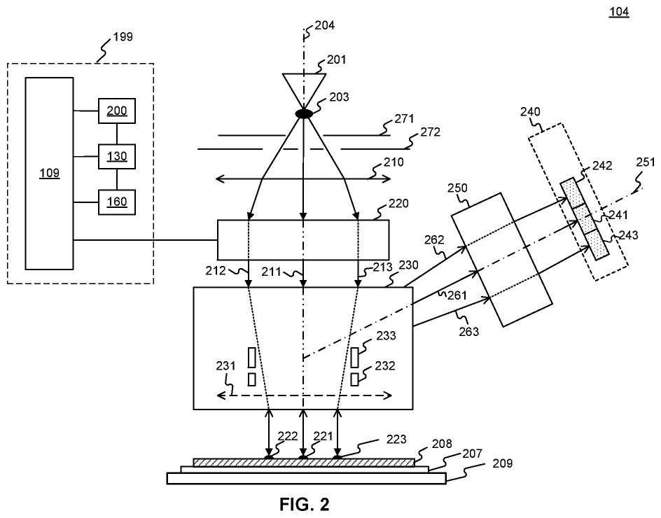

Reference is now made to FIG. 2, which is a schematic diagram illustrating an exemplary electron beam tool 104 including a multi-beam inspection tool that is part of the EBI system 100 of FIG. 1, consistent with some embodiments of the present disclosure. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a wafer 208 to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiment, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2 shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to control operations of one or more components of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto wafer 208 for inspection and may form, in the current embodiments, three probe spots 221, 222, and 223 on the surface of wafer 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of wafer 208. In response to incidence of primary beamlets 211, 212, and 213 or probe spots 221, 222, and 223 on wafer 208, electrons emerge from wafer 208 and generate three secondary electron beams 261, 262, and 263. Each of secondary electron beams 261, 262, and 263 typically comprise secondary electrons (having electron energy≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of wafer 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

As shown in FIG. 2, a wafer inspection system 199 (or “system 199”) may be provided by or communicatively coupled to source conversion unit 220. For example, system 199 may include an inspection image acquirer 200, a storage 130, a reference data acquirer 160 (or “a reference data acquirer 160”), and controller 109 that are communicatively coupled to each other. In some embodiments, inspection image acquirer 200, storage 130, or reference data acquirer 160 may be integrated as a module of controller 109 or system 199, or include a component that can be implemented in controller 109 or system 199. In some embodiments, system 199 or controller 109 may obtain and analyze reference data (e.g., GDS data) of IC layout on a wafer as disclosed herein. In some embodiments, system 199 or controller 109 may control an inspection process performed by a charged particle multi-beam system (e.g., system 104) based on the processed reference data as disclosed herein.

Inspection image acquirer 200 may comprise one or more processors. For example, inspection image acquirer 200 may comprise a computer, server, mainframe host, terminals, personal computer, any kind of mobile computing devices, and the like, or a combination thereof. Inspection image acquirer 200 may be communicatively coupled to electron detection device 240 of apparatus 104 through a medium such as an electrical conductor, optical fiber cable, portable storage media, IR, Bluetooth, internet, wireless network, wireless radio, among others, or a combination thereof. Inspection image acquirer 200 may receive a signal from electron detection device 240 and may construct an image. Inspection image acquirer 200 may thus acquire images of wafer 208. Inspection image acquirer 200 may also perform various post-processing functions, such as generating contours, superimposing indicators on an acquired image, and the like. Inspection image acquirer 200 may be configured to perform adjustments of brightness and contrast, etc. of acquired images.

In some embodiments, image acquirer 200 may acquire image data of a wafer based on an imaging signal received from electron detection device 240. An imaging signal may correspond to a scanning operation for conducting charged particle imaging. Acquired image data may correspond to a single image comprising one or more areas that may contain various features (e.g., repeating cell patterns or cell edges as disclosed herein) of wafer 208. Acquired image data may be stored in storage 130. The single image may be an original image that may be divided into a plurality of regions. Each of the regions may comprise one imaging area containing a pattern or a feature of wafer 208. The acquired image data may correspond to multiple images of one or more areas of wafer 208 sampled multiple times over a time sequence. The multiple images may be stored in storage 130. In some embodiments, controller 109 may be configured to perform image processing steps as disclosed herein to inspection image data associated with the multiple images of one or more areas of wafer 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of wafer 208, and thereby can be used to reveal any defects that may exist in the wafer.

Reference data acquirer 160 may comprise one or more processors. For example, reference data acquirer 160 may comprise a computer, server, mainframe host, terminals, personal computer, any kind of mobile computing devices, and the like, or a combination thereof. Reference data acquirer 160 may be communicatively coupled to storage 130 or other types of internal or external storage (e.g., design database) configured to store reference data (e.g., GDS data, or design data) used for design and inspection of integrated circuit layout on a wafer. Reference data acquirer 160 may acquire reference data through a medium such as an electrical conductor, optical fiber cable, portable storage media, IR, Bluetooth, internet, wireless network, wireless radio, among others, or a combination thereof. Reference data may be associated with design of IC layout on a wafer. Reference data may be obtained through software simulation, or geometric design and Boolean operations. In some embodiments, reference data may be stored in a data structure, such as a GDS data file or in any suitable data format.

In some embodiments, controller 109 may analyze the reference data acquired by reference data acquirer 160. For example, as disclosed in the present disclosure, controller 109 may process the GDS data files to identify repeating patterns corresponding to cell arrays and edges of the cells respectively. Based on the processed GDS data files, controller 109 may also generate control signals to control operations of source conversion unit 220 or other components of electron beam tool 104 to inspect certain areas of wafer 208 using predetermined parameters. For example, the control signals generated by controller 109 may be used to control primary beamlets 211, 212, and 213 to scan probe spots 221, 222, and 223 across certain scanning areas on wafer 208, such as regions corresponding to the identified cell arrays or cell edges.

Storage 130 may be a storage medium such as a hard disk, random access memory (RAM), cloud storage, other types of computer readable memory, and the like. Storage 130 may be coupled with inspection image acquirer 200 and may be used for saving scanned raw image data as original images, and post-processed images. Storage 130 may also be coupled with reference data acquirer 160 and used for saving reference data and post-processed reference data.

In some embodiments, controller 109 may control motorized stage 209 to move wafer 208 during inspection of wafer 208. In some embodiments, controller 109 may enable motorized stage 209 to move wafer 208 in a direction continuously at a constant speed. In other embodiments, controller 109 may enable motorized stage 209 to change the speed of the movement of wafer 208 overtime depending on the steps of scanning process.

As show in FIG. 2, controller 109 may be electronically connected to electron beam tool 104. As disclosed herein, controller 109 may be a computer configured to execute various controls of electron beam tool 104. In some embodiments, inspection image acquirer 200, reference data acquirer 160, storage 130, and controller 109 may be integrated together as one control unit.

Although FIG. 2 shows that electron beam tool 104 uses three primary electron beams, it is appreciated that electron beam tool 104 may any suitable number of primary electron beams. The present disclosure does not limit the number of primary electron beams used in electron beam tool 104. Compared with a single charged-particle beam imaging system (“single-beam system”), a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries. adapting to different throughputs and resolution requirements.

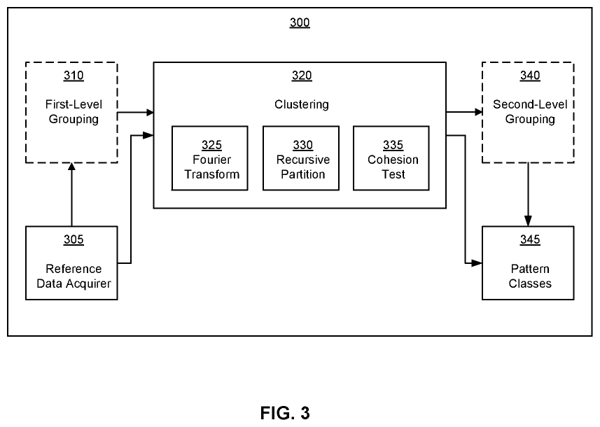

FIG. 3 is a block diagram of an example system 300 for processing reference data (e.g., GDS data), consistent with some embodiments of the present disclosure. In some embodiments, system 300 includes a reference data acquirer 305, a first-level grouping component 310, a clustering component 320, a second-level grouping component 340, and an output component 345 for outputting classes (e.g., or clusters, groups, sets, or subsets, etc.) of patterns. In some embodiments, clustering component 320 further includes a Fourier transform component 325, a recursive partition component 330, and a cohesion test component 335. In some embodiments, reference data analysis may include a first-level grouping process performed by first-level grouping component 310, a clustering process performed by clustering component 320, followed by a second-level grouping process performed by second-level grouping component 340. In some embodiments, the first-level grouping or the second-level grouping process may be optional for processing the reference data.

It is appreciated that system 300 may include one or more components or modules that are integrated as parts of a charged-particle beam inspection system (e.g., electron beam inspection system 100 of FIG. 1). System 300 may also include one or more components or modules separate from and communicatively coupled to the charged-particle beam inspection system. System 300 may comprise one or more processors and storage memories. For example, system 300 may comprise a computer, server, mainframe host, terminals, personal computer, any kind of mobile computing devices, and the like, or a combination thereof. In some embodiments, system 300 may include one or more components, e.g., software modules, hardware modules, or combinations thereof, that can be implemented in controller 109 or system 199 as disclosed herein.

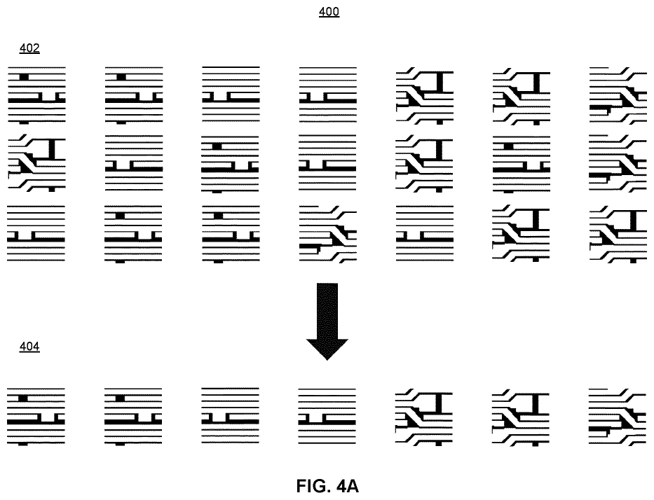

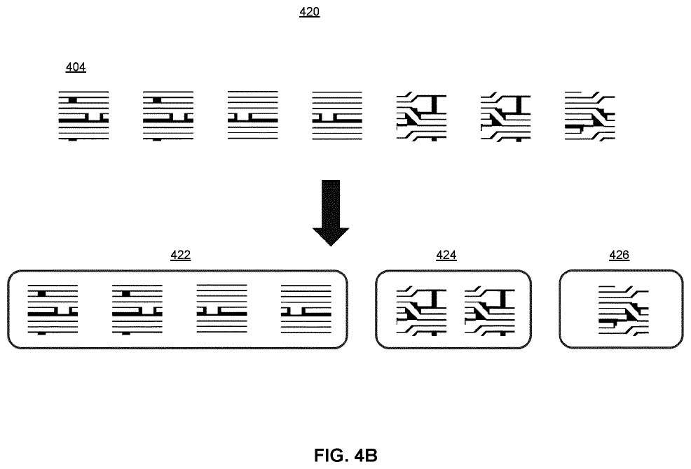

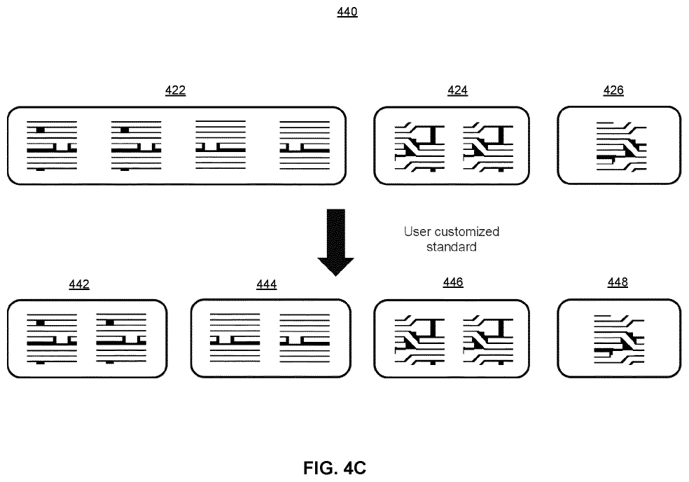

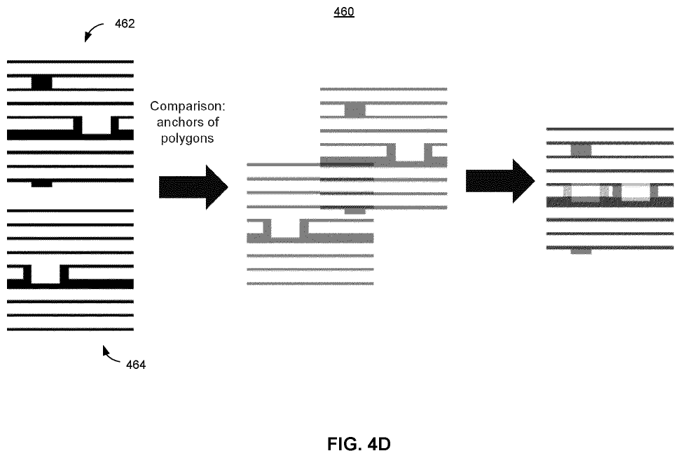

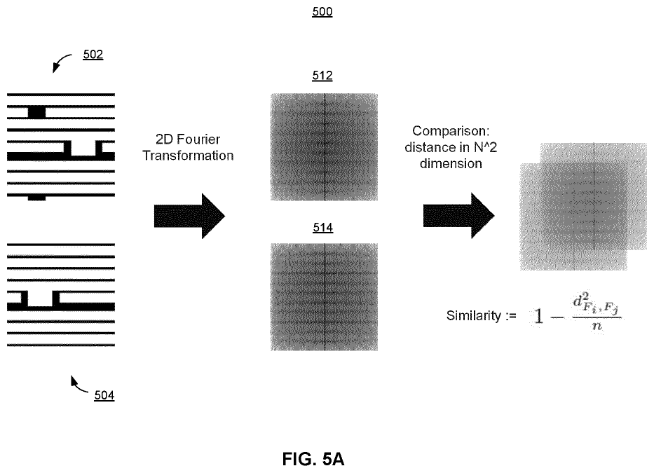

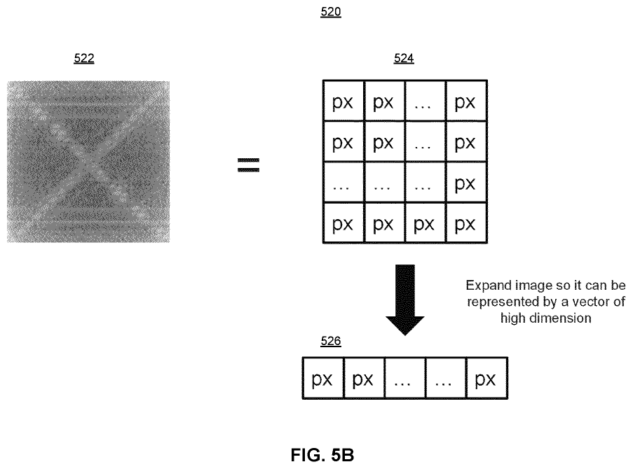

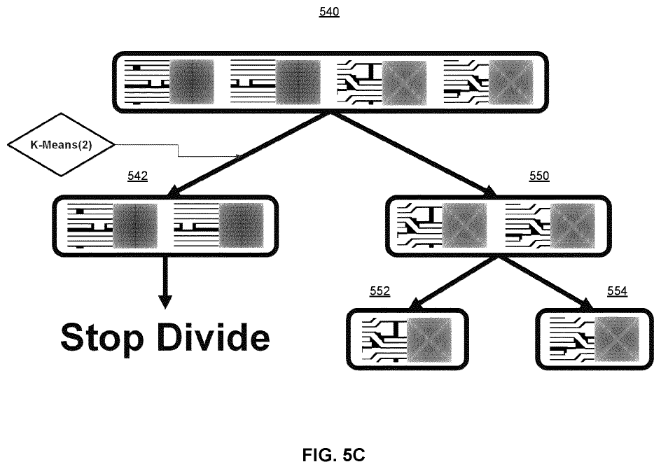

In some embodiments as shown in FIG. 3, system 300 may include reference data acquirer 305. Reference data acquirer 305 may be configured to obtain reference data, e.g., including a plurality of patterns as shown in FIGS. 4A-4D, 5A, and 5C, to be processed by system 300. The plurality of patterns in the acquired reference data may correspond to patterns on a mask used for patterning a portion of a wafer (e.g., a die), or patterns printed via a lithography process on a portion of a wafer (e.g., a die). In some embodiments, reference data acquirer 305 can be substantially similar to reference data acquirer 160 in FIG. 2. In some embodiments, reference data acquirer 305 may be different from reference data acquirer 160. For example, reference data acquirer 305 may be included or implemented in a computing device separate from the charged-particle beam inspection system.

In some embodiments, the reference data as disclosed herein may be in Graphic Database System (GDS) format, Graphic Database System II (GDS II) format, an Open Artwork System Interchange Standard (OASIS) format, a Caltech Intermediate Format (CIF), etc. In some embodiments, reference data may comprise IC design layout on wafer 208 under inspection. The IC design layout may be based on a pattern layout for constructing the wafer. The IC design layout may correspond to one or more photolithography masks or reticles used to transfer features from the photolithography masks or reticles to a wafer. In some embodiments, reference data in GDS or OASIS, among others, may comprise feature information stored in a binary file format representing planar geometric shapes, text, and other information related to wafer design layout.

In some embodiments, the reference data, such as GDS data files, may correspond to a design architecture to be formed on a plurality of hierarchical layers on a wafer. The reference data may be presented in image files and may include characteristics information (e.g., shape, dimension, etc.) for various patterns on different layers that are to be formed on the wafer. For example, reference data may include information associated with various structures, devices, and systems to be fabricated on the wafer, including but not limited to, substrates, doped regions, poly-gate layers, resistance layers, dielectric layers, metal layers, transistors, processors, memories, metal connections, contacts, vias, system-on-chips (SoCs), network-on-chips (NoCs), or any other suitable structures. Reference data may further include IC layout design of memory blocks, logic blocks, interconnects, etc.

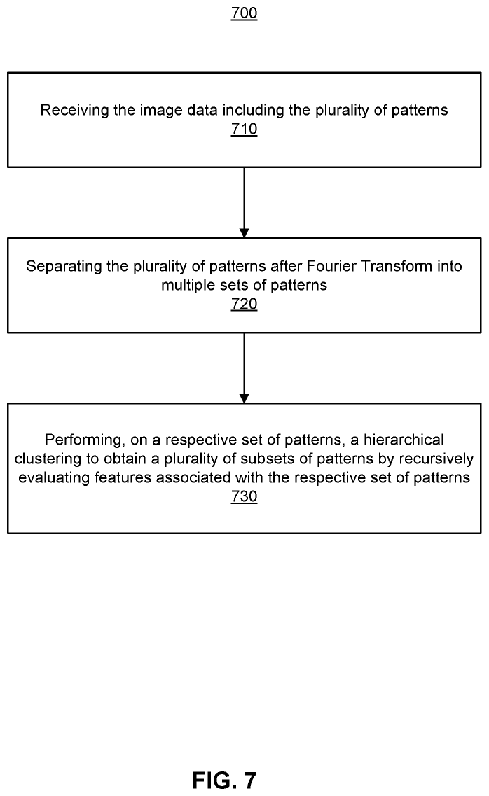

In some embodiments, system 300 may include first-level grouping component 310 configured to process the reference data obtained from reference data acquirer 305. In some embodiments, first-level grouping component 310 may analyze the one or more patterns and group the patterns (e.g., by pattern types, shapes, numbers, density, etc.). For example, first-level grouping component 310 may compare a plurality of patterns in the reference data to classify (e.g., categorize) identical patterns in a same group (e.g., class, category, bin, etc.), for example, as shown in FIG. 4A. First-level grouping component 310 may compare the geometrical shape and features between patterns within one or more pairs from the reference data. In some embodiments, first-level grouping component 310 may be configured to perform one or more steps as disclosed with reference to FIG. 7. In some embodiments, first-level grouping component 310 may be a part of the charged-particle beam inspection system (e.g., including one or more components or modules that can be implemented in controller 109 or system 199). In some embodiments, first-level grouping component 310 may be included in a computing device separate from and communicatively coupled to the charged-particle beam inspection system.

In some embodiments, system 300 may include clustering component 320 configured to apply one or more clustering algorithms as disclosed herein for clustering the patterns from the reference data. Clustering component 320 may apply clustering algorithms to grouped patterns obtained from first-level grouping component 310 (e.g., representative patterns as shown in FIG. 4B) or to patterns in the reference data acquired by reference data acquirer 305. In some embodiments, as illustrated in FIG. 4B, clustering component 320 may use (DBSCAN) algorithm to analyze whether similarity between two or more patterns are over a predetermined threshold to determine whether to merge the patterns into the same cluster.

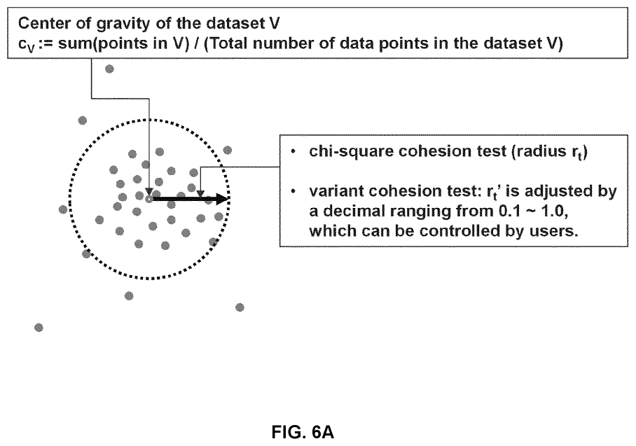

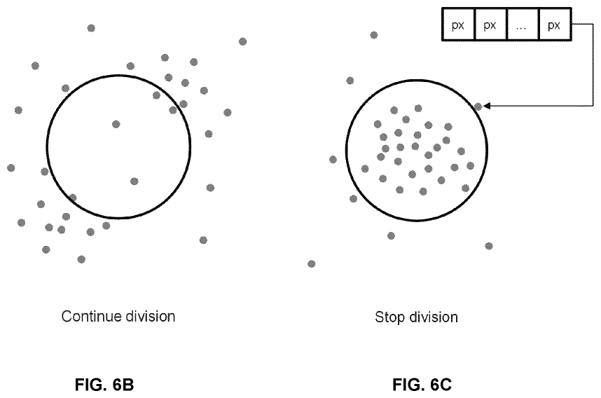

In some embodiments, a Fourier Transform component (e.g., Fourier Transform component 325 of clustering component 320) may perform Fourier Transform (e.g., 1-D or 2-D Fourier Transform, also referred to as Fourier Transformation) on a plurality of patterns to render the images in frequency domain. For example, as illustrated in FIG. 5A, patterns 502, 504 can be transformed to Fourier Transformed based images (e.g., Fourier domain images, or frequency domain images) 512, 514. In some embodiments, a Fourier Transform component (e.g., Fourier Transform component 325) can convert Fourier Transform based images into high-dimensional vectors. For example, as illustrated in FIG. 5B, Fourier Transform based image 522 can be converted to vector 526. In some embodiments, Fourier Transform component 325 can further determine a distance (e.g., Euclidean distance) between feature points of the Fourier Transform based vectors and a cluster centroid. The distance can be used for evaluating similarity between the patterns as illustrated in FIGS. 5A-5C and 6A-6C.

In some embodiments, recursive partition component 330 of clustering component 320 may perform a hierarchical clustering process (e.g., process 540) for partitioning the Fourier Transform based features (e.g., the images or vectors as disclosed herein) in frequency domain to obtain a plurality of clusters. In some embodiments, as illustrated in FIG. 5C, recursive partition component 330 uses a clustering algorithm, such as a k-means clustering algorithm or any other suitable clustering algorithm, for the recursive partition. For example, recursive partition component 330 may first partition the patterns into a certain number of groups (or subsets). Within a respective group, recursive partition component 330 further performs recursive partition, until the condition or threshold for stopping the recursive partition is met.

In some embodiments, cohesive test component 335 of clustering component 320 may determine a condition or threshold used for stopping the recursive partition. The condition or threshold may be associated with a similarity threshold, a maximum level of hierarchy of the hierarchical clustering process, or a minimum number of vectors included in a subset before further partition, etc. In some embodiments, cohesion test component 335 can use a cohesion test. For example, as illustrated in FIG. 6A, the cohesion test may include a chi-square distribution cohesion test or a variant cohesion test used for determining a radius of a test circle. As illustrated in FIGS. 6B-6C, the test circle can be used for evaluating whether there are enough datapoints within the test circle to stop recursive partition. In some embodiments, the user can adjust the radius to customize the size of the test circle for directly or indirectly tuning one or more parameters used in the recursive partition process. Cohesion test component 335 may further determine a cohesion degree (e.g., a ratio between a number of datapoints inside the test circle and the total number of datapoints) and compare the cohesion degree with a threshold value to determine whether to stop or continue the recursive partition (e.g., FIGS. 6B-6C).

In some embodiments, clustering component 320 may be configured to perform one or more steps as disclosed with reference to FIG. 7. In some embodiments, clustering component 320 may be a part of the charged-particle beam inspection system (e.g., including one or more components or modules that can be implemented in controller 109 or system 199). In some embodiments, clustering component 320 may be included in a computing device separate from and communicatively coupled to the charged-particle beam inspection system.

In some embodiments, system 300 may include second-level grouping component 340 configured to further process the grouped patterns obtained from clustering component 320. Second-level grouping component 340 may analyze patterns within and among respective groups or clusters of patterns to further merge or split based on pattern similarity (e.g., FIG. 4C). In some embodiments, the similarity standard may be customized by a user. In some embodiments, second-level grouping component 340 may be configured to perform one or more steps as disclosed with reference to FIG. 7. In some embodiments, second-level grouping component 340 may be a part of the charged-particle beam inspection system (e.g., including one or more components or modules that can be implemented in controller 109 or system 199). In some embodiments, second-level grouping component 340 may be included in a computing device separate from and communicatively coupled to the charged-particle beam inspection system.

In some embodiments, system 300 may output the pattern groups or clusters, e.g., using indicators such as coordinates on a wafer or a die, to be used during inspection. In some embodiments, output component 345 may be a part of the charged-particle beam inspection system (e.g., including one or more components or modules that can be implemented in controller 109 or system 199). In some embodiments, output component 345 may be included in a computing device separate from and communicatively coupled to the charged-particle beam inspection system.

FIG. 4A is an example process of performing a first-level grouping process 400, on a plurality of patterns 402 in the reference data, e.g., corresponding to a portion of a GDS image, to obtain a plurality of representative patterns 404, in accordance with some embodiments of the present disclosure. In some embodiments, the plurality of patterns 402 correspond to patterns on a mask used for patterning a portion of a wafer, such as a die. In some embodiments, the plurality of patterns 402 correspond to patterns printed via a lithography process on a portion of a wafer, e.g., a die.

In some embodiments, the first-level grouping process 400 is performed based on comparison of geometric shapes between the plurality of patterns 402. For example, each pair of patterns within the plurality of patterns 402 are compared, and based on the comparison results, the plurality of patterns 402 are separated into multiple groups. In some embodiments, as a result of the first grouping process 400, the patterns within a group are geometrically identical to each other and are put into one bin. In some embodiments, a respective representative pattern 404 represents identical pattern(s) in the corresponding group obtained from the first-level grouping process.

FIG. 4B is an example process of performing a clustering process 420 on the grouping results obtained from the first grouping process 400 as illustrated in FIG. 4A, in accordance with some embodiments of the present disclosure. In some embodiments, the clustering process 420 is performed on the grouped patterns in the reference data that are represented by representative patterns 404 of respective groups. In some embodiments, patterns of two bins obtained from the process in FIG. 4A are compared and the similarity can be quantified and computed using any suitable clustering algorithms. For example, the clustering process 420 can use a density-based spatial clustering of applications with noise (DBSCAN) algorithm. In some embodiments, if the similarity between two representative patterns is over a predetermined threshold, two bins are merged, e.g., as shown in new groups (or bins) 422 or 424. Otherwise, the group represented by the representative pattern 426 stays unmerged. In some embodiments, the clustering process 420 runs until all bins are evaluated.

FIG. 4C is an example process of performing a second-level grouping process 440 on the clustering results obtained from the clustering process 420 as illustrated in FIG. 4B, in accordance with some embodiments of the present disclosure. In some embodiments, the patterns from respective bins obtained in process 420 of FIG. 4B are further analyzed to obtain different classes of patterns, such as classes 442, 444, 446, and 448 in FIG. 4C. In some embodiments, patterns that are more similar to each other are classified into a class, whereas patterns that are not sufficiently similar to each other are further split into different classes, such as bin 422 split into classes 442 and 444. In some embodiments, the similarity standard for classifying the patterns in process 440 may be customized by a user. The second-level grouping process may use a different standard for comparing similarities between patterns than the first-level grouping process. For example, in the first-level grouping, patterns that are identical to each other are placed in the same group (or bin), whereas in the second-level grouping, patterns that are sufficiently similar, e.g., with differences below a certain threshold, are placed in the same group. In some embodiments, the standard used for comparing the patterns during the first-level grouping or the second-level grouping may be associated with geometric shapes, sizes, feature types, densities, distances between feature points, etc. of the patterns. In some embodiments, the patterns may be compared in pairs in the second-level grouping or the first-level grouping.

Reference is now made to FIG. 4D, a diagram illustrating an example of comparing two patterns during the grouping or clustering process as illustrated in FIGS. 4A-4C, in accordance with some embodiments of the present disclosure. In some embodiments, geometric shapes of a pair of patterns, e.g., patterns 462 and 464, are compared during the clustering process 420 using a suitable clustering algorithm, such as the DBSCAN algorithm as disclosed herein. In some embodiments, because any two patterns out of the total number (e.g., n) of patterns are compared, the process can take n² times of comparison, which is a time-consuming process. Further, as shown in FIG. 4D, two pattern images 462 and 464 are overlapped to measure the differences between the images. This overlapping, however, may overlook the possibility that two identical patterns may appear to be different due to shifting or rotation relative to each other. As a result, different bins or classes may include duplicate patterns, further resulting in increased inspection time and wasted resource consumption.

FIGS. 5A-5C and 6A-6B illustrate an example hierarchical clustering process based on Fourier Transform based reference data, in accordance with some embodiments of the present disclosure. FIG. 5A illustrates an example process 500 of performing Fourier Transform on a plurality of patterns in the reference data (e.g., corresponding to a portion of a GDS image), in accordance with some embodiments of the present disclosure. The patterns may be obtained from grouped patterns from first-level grouping component 310 or reference data from reference data acquirer 305. In some embodiments, Fourier Transform component 325 can apply 2-D Fourier Transform to the patterns, e.g., patterns 502 and 504, to render the images in frequency domain, as shown in images 512 and 514.

In some embodiments, a distance between feature points of the Fourier Transform based reference data in frequency domain can be determined. For example, Euclidean distance between two feature points between images 512 and 514 and a cluster centroid can be determined. The distance can be used for determining a similarity between vectors corresponding to the two patterns 512 and 514 as disclosed herein.

FIG. 5B illustrates an example process 520 of converting Fourier Transform based reference images, e.g., Fourier Transform based image 522, into vectors, in accordance with some embodiments of the present disclosure. In some embodiments, pixels of image 522 are analyzed, e.g., to obtain pixel values for respective pixels as shown in diagram 524. Based on the pixel information, image 522 is then expanded into a high-dimensional vector 526 in frequency domain. The distance may be calculated based on the Fourier Transform based vectors.

FIG. 5C illustrates a diagram showing an example hierarchical clustering process 540 for partitioning the Fourier Transform based features in frequency domain to obtain a plurality of clusters, in accordance with some embodiments of the present disclosure. In some embodiments, recursive partition component 330 uses a clustering algorithm, such as a k-means clustering algorithm, or any other suitable clustering algorithm, to recursively partition a plurality of Fourier Transform based features into a plurality of clusters. In some embodiments, the distance between a vector and a cluster centroid is compared with a predetermined threshold for determining whether the vector is included in this cluster. The vectors being close enough to the cluster centroid, e.g., with distances within the predetermined threshold, are contained in the corresponding cluster. In some embodiments, the clustering algorithm uses a predetermined number of clusters (e.g., a fixed number of clusters) when partitioning the Fourier Transform based features. In some embodiments, hierarchical clustering process 540 does not set a predetermined or a fixed number of clusters. Rather, process 540 uses a condition or a threshold for stopping the recursive partition, such as a stopdivide function.

In some embodiments, for the hierarchical clustering process disclosed herein, recursive partition component 330 first partitions the entire dataset into multiple subsets. In some embodiments, the first level of partition may use a suitable clustering algorithm, such as k-means algorithm for partitioning the entire dataset into a certain number of subsets, e.g., two or more subsets, based on similarity (e.g., or distance to the cluster centroid) of the Fourier Transformed feature vectors. For example, as shown in FIG. 5C, the original dataset 540 can first be partitioned into a subset 542 and another subset 550 using k-means algorithm, where the Fourier Transformed features within each subset have distances close to the cluster centroid. Next, recursive partition component 330 recursively partitions a respective subset, e.g., subset 550, into multiple subsets, e.g., subsets 552 and 554, at the next level(s). When the condition or threshold for stopping the recursive partition is met, e.g., for subset 542, the recursive partition is stopped. Subsets 552 and 554 are also further partitioned respectively until the condition or threshold for stopping the recursive partition is met.

In some embodiments, the condition or threshold may be associated with a similarity threshold that is used to compare with similarity of the Fourier Transformed feature vectors within a subset to determine whether to stop recursive partition. In some embodiments, the condition or threshold may be associated with a maximum level of hierarchy of the hierarchical clustering process. For example, the recursive partition stops when the level of subset reaches the maximum level (or the deepest level) of the threshold. In some embodiments, the condition or threshold may be associated with a minimum number of vectors included in a subset before further partition. For example, the recursive partition stops in one subset when the number of vectors in this subset is fewer than the minimum number threshold.

In some embodiments, cohesion test component 335 of FIG. 3 can use a cohesion test in a StopDivide function. For example, the cohesion test can be used to measure how vectors integrate or how cohesive the datapoints are in a subset. In some embodiments, as illustrated in FIG. 6A, the cohesion test can include a chi-square distribution cohesion test, with the assumption that components of all dimensions of vectors in a cluster or a subset follow the normal distribution (or another suitable distribution function). Each data point in FIG. 6A represents a feature vector in frequency domain that corresponds to a Fourier Transform based feature image. In some embodiments, given a dataset V of a cluster, a cluster centroid cv can be determined, and an average distance rᵥ (e.g., a mean distance) of the dataset V can be determined based on the respective distances between the vectors in the cluster and the cluster centroid cᵥ. Then, based on the known distribution function (e.g., a normal distribution, or another function that fits the dataset), a radius for a test circle rₜ, using r₉₀, e.g., a radius of 90 percent credition as an example, can be calculated, where r₉₀ corresponds to an expectation that 90% of the datapoints of the cluster are included in a circle centered at cᵥ with a radius of r₉₀. Next, as disclosed in FIGS. 6B-6C below, a cohesion degree, e.g., a ratio between the actual number of datapoints included in the test circle (e.g., centered at cᵥ with radius rₜ of r₉₀) and the total number of datapoints in dataset V can be calculated. The ratio is compared to a predetermined threshold (e.g., 90%) for determining whether such dataset is sufficiently cohesive and whether to stop or continue the recursive partition accordingly.

In some embodiments, the chi-square distribution cohesion test may work better with a cluster containing a large number of datapoints. Further, the chi-square distribution cohesion test considers the distance between vectors and the cluster centroid, but may not consider the distances between vectors. For example, if vectors in a cluster follow a normal distribution, but with variance greater than an acceptable threshold (e.g., distances between vectors are not sufficiently close, or patterns are in fact not sufficiently similar), the chi-square cohesion test may not effectively identify such issue. The chi-square cohesion test may erroneously stop the recursive partition, resulting in poor clustering quality.

In some embodiments, as also illustrated in FIG. 6A, the cohesion test can include a variant cohesion test to address the above problems. For example, the variant cohesion test provides a user-customizable radius (rₜ′) for defining a test circle based on a user selected coefficient (θ) between 0.1 to 1.0 to adjust the calculated radius, e.g., such as r₉₀ as disclosed herein, instead of a fixed radius used in the chi-square distribution cohesion test (e.g., rₜ′=θrₜ). For example, a user can choose or input a coefficient θ, such as a decimal 0.1, 0.2, 0.3, 0.4, 0.5, 0.6, 0.7, 0.8, 0.9, or 1.0, for adjusting the radius rₜ′ of the test circle to be larger or smaller, where the test circle is used for determining whether there are enough datapoints within the test circle to stop recursive partition as disclosed below (e.g., whether the dataset V is sufficiently cohesive according to the distribution function). The variant cohesion test can provide the user freedom and convenience to customize one or more parameters (e.g., how similar the vectors are in a cluster) used for determining when to stop the recursive partition process. In some embodiments, the user can also select what is the maximum number of vectors the user wants to include in a cluster.

After determining the radius defining the test circle, a cohesion degree is determined and compared to a certain threshold to determine whether to stop the recursive partition. In some embodiments, the cohesion degree is a ratio between a number of datapoints (e.g., corresponding to Fourier Transform based feature vectors) inside the test circle and the total number of datapoints (e.g., vectors) in the subset (e.g., cluster). In some embodiments, the threshold may be a predetermined value, such as 90%, 85%, or 80%, etc. The threshold may correspond to the test radius, e.g., 90% corresponding to r₉₀. The threshold may also be selected or adjusted by the user or pre-set by the system.

In some embodiments, as shown in FIG. 6B, if the cohesion degree is not over the certain threshold, e.g., not enough datapoints are within the test circle defined by the radius rₜ, the recursive partition of the current cluster (or the current subset) continues. As shown in FIG. 6C, in some embodiments, the recursive partition stops if the cohesion degree is more than a certain threshold, e.g., 90 percent, indicating that the vast majority of the datapoints representing feature vectors are sufficiently close to the cluster centroid.

In some embodiments, the hierarchical clustering process disclosed in FIGS. 5A-5C and 6A-6B can be performed independently from or in combination with other grouping or clustering processes, such as the first-level grouping or the second-level grouping as disclosed in FIGS. 4A and 4C.

As disclosed herein, the recursive partition used in the clustering algorithm does not need to compare each and every pair of data points. Instead, the hierarchical clustering process first partitions the entire dataset into multiple subsets. Then, the subsets are respectively partitioned recursively into subsets at subsequent levels, until the condition for stopping the recursive partition is met. As such, the hierarchical clustering process can be less time-consuming. For example, compared to N² times of comparison performed in FIG. 4D, the time complexity of the hierarchical clustering process as disclosed herein is

N log(N).

Furthermore, the clustering algorithm is based on characteristics, such as distances, associated with Fourier Transform based features (e.g., images or vectors) in frequency domain, which can take into consideration the orientational deviation, such as translational shift, or rotation, etc., between the patterns when comparing the vectors. As such, partitioning identical patterns into different clusters can be avoided, and thus the clustering process can be more accurate and efficient.

Additionally, the user can control or customize the clustering process, e.g., by adjusting or selecting a parameter, e.g., a radius for defining a test circle, used for evaluating whether to stop the recursive partition. Indirectly through the impact of the radius or directly, the user can customize one or more parameters associated with the recursive partition, such as how similar the patterns can be within a cluster, a maximum number of vectors to be included in a cluster, a maximum number of clusters, or a maximum level of hierarchy of the partition, etc. As disclosed herein, the user can conveniently select a radius of the test circle for tuning one or more of these parameters for the recursive partition process.

FIG. 7 is a process flowchart representing an example method 700 for processing reference data, e.g., grouping patterns extracted from the reference data, in accordance with some embodiments of the present disclosure. In some embodiments, one or more steps are performed by one or more components of apparatus 300 in FIG. 3, controller 109 or system 199 in FIG. 2, or system 100 in FIG. 1. In some embodiments, method 700 is performed on a plurality of patterns on a mask for patterning a portion of a wafer (e.g., a die). In some embodiments, method 700 can also be performed on a plurality of patterns printed (e.g., via lithography) on a portion of a wafer (e.g., a die).

As shown in FIG. 7, in step 710, image data, such as reference image data, including a plurality of patterns is received. For example, the image data may be obtained by reference data acquirer 305 in FIG. 3, or reference data acquirer 160 in FIG. 2. The reference data may be obtained from storage 130 in FIG. 2, or any other suitable IC layout design database. The image data may be in any suitable data format as disclosed herein, such as GDS data files corresponding to an IC design architecture to be formed on a plurality of hierarchical layers on a wafer (e.g., wafer 208). The image data may include patterns on a mask to be used for forming features on at least a portion of a wafer, such as a die. The image may also include patterns obtained from inspection performed on features printed on wafers.

In some embodiments, Fourier Transform component 325 may perform Fourier Transform on the plurality of patterns (e.g., patterns 502, 504, FIG. 5A) to obtain a plurality of Fourier Transform based images (e.g., image 512, 514, FIG. 5A) in frequency domain. In some embodiments, Fourier Transform component 325 may further convert Fourier Transform based images to high-dimensional vectors, as illustrated in FIG. 5B. Similarity between the patterns may be evaluated for grouping the patterns. In some embodiments, a distance can be calculated for a respective vector corresponding to a pattern after Fourier Transform, and the distance may be a Euclidean distance between the respective vector and a cluster centroid. In some embodiments, datapoints representing vectors that are sufficiently close to the cluster centroid may be included in the same cluster.

In step 720, the plurality of patterns, after performing the Fourier Transform and vectorization, are separated into multiple sets of patterns (e.g., e.g., subsets 542, 550, FIG. 5C). In some embodiments, the Fourier Transform based images are separated using a k-means algorithm, where the Fourier Transformed features within each subset have distances close to the cluster centroid.

In step 730, recursive partition component 330 performs a hierarchical clustering on a respective set of patterns, to obtain a plurality of subsets of patterns by recursively evaluating features associated with the respective set of patterns. In some embodiments, as illustrated in FIG. 5C, partition component 330 performs recursive partitions on the respective set of patterns based on results of recursively evaluating the features at respective hierarchical levels. The feature may be related to similarity between the patterns of the respective set of patterns, such as a cohesion degree determined based on whether the patterns within the respective set of patterns are sufficiently similar.

In some embodiments, cohesion test component 335 can perform a cohesion test for evaluating the features as illustrated in FIGS. 6A-6C. Cohesion test component 335 can determine the cohesion degree of a respective set of patterns. For example, the cohesion degree can be determined as a ratio between a number of datapoints inside the test circle and the total number of datapoints (e.g., FIG. 6A). The cohesion degree can be compared with a threshold value to determine whether to stop or continue the recursive partition (e.g., FIGS. 6B-6C). For example, if the cohesion degree, e.g., the ratio, is determined to be not greater than the predetermined threshold as illustrated in FIG. 6B, the recursive partition of the current cluster (or the current subset) continues. If the cohesion degree is determined to be greater than the predetermined threshold as illustrated in FIG. 6C, the recursive partition of the current cluster (or the current subset) stops.

In some embodiments, a radius of the test circle can be determined using a chi-square cohesion test, such as r₉₀ as illustrated in FIG. 6A. In some embodiments, the radius of the test circle can be determined using a variant cohesion test as illustrated in FIG. 6A, where the radius is a user-customizable radius.

In some embodiments, through the variant cohesion test, the user can adjust the radius of the test circle to be larger or smaller. As disclosed herein, the user may be provided with an option to select or adjust other parameters used for determining when to stop the recursive partition process. Such parameters include, but are not limited to, a size of the radius, how similar the vectors are in a cluster, a maximum number of vectors included in a cluster, a maximum level of hierarchy of the recursive partition, or a minimum number of vectors included in a subset before further partition, etc. In some embodiments, the processes and algorithms disclosed herein regarding grouping the reference data can also be used for analyzing and grouping the inspection image data after scanning the wafer surface.

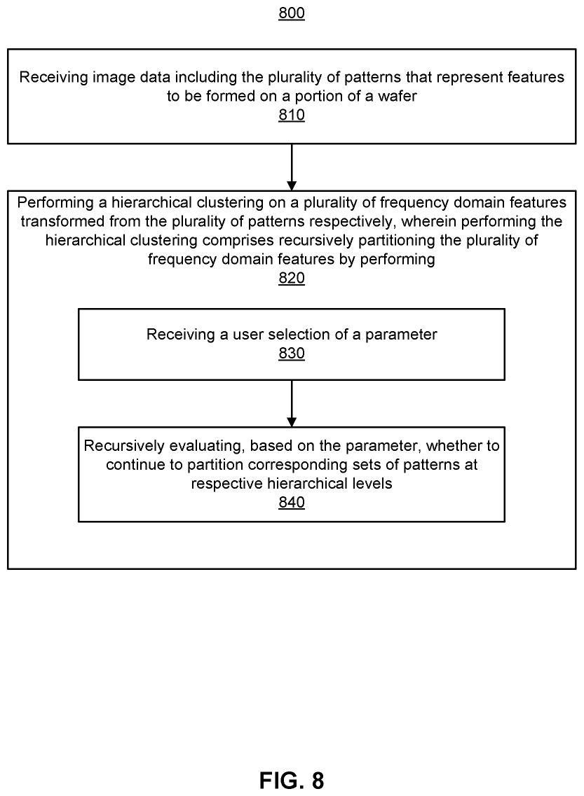

FIG. 8 is a process flowchart representing an example method 800 for processing reference data, e.g., image data including grouping patterns extracted from the reference data, in accordance with some embodiments of the present disclosure. In some embodiments, one or more steps are performed by one or more components of apparatus 300 in FIG. 3, controller 109 or system 199 in FIG. 2, or system 100 in FIG. 1. In some embodiments, method 800 is performed on a plurality of patterns on a mask for patterning a portion of a wafer (e.g., a die). In some embodiments, method 800 can also be performed on a plurality of patterns printed (e.g., via lithography) on a portion of a wafer (e.g., a die).

As shown in FIG. 8, in step 810, image data, such as reference image data, including a plurality of patterns is received. For example, the image data may be obtained by reference data acquirer 305 in FIG. 3, or reference data acquirer 160 in FIG. 2. The reference data may be obtained from storage 130 in FIG. 2, or any other suitable IC layout design database. The image data may be in any suitable data format as disclosed herein, such as GDS data files corresponding to an IC design architecture to be formed on a plurality of hierarchical layers on a wafer (e.g., wafer 208). The image data may include patterns on a mask to be used for forming features on at least a portion of a wafer, such as a die. The image may also include patterns obtained from inspection performed on features printed on wafers.

In some embodiments, Fourier Transform component 325 may perform Fourier Transform on the plurality of patterns (e.g., patterns 502, 504 of FIG. 5A) to obtain a plurality of frequency domain features, such as Fourier Transform based images (e.g., image 512, 514 of FIG. 5A), or high-dimensional vectors as illustrated in FIG. 5B. Similarity between the patterns may be evaluated for grouping the patterns. In some embodiments, a distance can be calculated for a respective vector corresponding to a pattern after Fourier Transform, and the distance may be a Euclidean distance between the respective vector and a cluster centroid. In some embodiments, datapoints representing vectors that are sufficiently close to the cluster centroid may be included in the same cluster. In some embodiments, the plurality of frequency domain features are separated into multiple first-level sets of patterns (e.g., e.g., subsets 542, 550 of FIG. 5C). In some embodiments, the frequency domain features, such as the Fourier Transform based images, are separated using a k-means algorithm, where the Fourier Transformed features within each subset have distances close to the cluster centroid.

In step 820, recursive partition component 330 performs a hierarchical clustering on the plurality of frequency domain features transformed from the plurality of patterns respectively. In some embodiments, recursive partition component 330 recursively partitions the plurality of frequency domain features. In some embodiments, a user selection of a parameter is received. The parameter may be related to evaluation of the plurality of patterns during the recursive partition. For example, as disclosed herein, the user can adjust the radius of the test circle to be larger or smaller through the variant cohesion test. The user may be provided with an option to select or adjust one or more parameters used for determining whether to continue the recursive partition process.

In some embodiments, as illustrated in FIG. 5C, partition component 330 performs recursive partitions on the respective set of patterns based on results of recursively evaluating the features at respective hierarchical levels. The feature may be related to similarity between the patterns of the respective set of patterns, such as a cohesion degree determined based on whether the patterns within the respective set of patterns are sufficiently similar.

In some embodiments, as illustrated in FIGS. 6A-6C, cohesion test component 335 can determine a cohesion degree of a set of patterns. For example, the cohesion degree can be determined as a ratio between a number of datapoints inside the test circle and the total number of datapoints (e.g., FIG. 6A). The cohesion degree can be compared with a threshold value to determine whether to stop or continue the recursive partition (e.g., FIGS. 6B-6C). In some embodiments, a radius of the test circle can be determined using a chi-square cohesion test, such as r₉₀ as illustrated in FIG. 6A. In some embodiments, the radius of the test circle can be determined using a variant cohesion test as illustrated in FIG. 6A, where the radius is a user-customizable radius.

A non-transitory computer readable medium may be provided that stores instructions for a processor of a controller (e.g., controller 109 of FIGS. 1-2) to carry out, among other things, image inspection, image acquisition, stage positioning, beam focusing, electric field adjustment, beam bending, condenser lens adjusting, activating charged-particle source, beam deflecting, and for processing reference data such as described above regarding method 700. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method of grouping a plurality of patterns extracted from image data, the method comprising:
receiving the image data including the plurality of patterns that represent features to be formed on a portion of a wafer;
separating the plurality of patterns after Fourier Transform into multiple sets of patterns; and
performing, on a respective set of patterns, a hierarchical clustering to obtain a plurality of subsets of patterns by recursively evaluating features related to similarity between patterns within the respective set of patterns.
2. The method of clause 1, further comprising:
performing Fourier Transform on the plurality of patterns to obtain, respectively, a plurality of Fourier Transform based images in a frequency domain; and
obtaining a plurality of vectors based on the plurality of Fourier Transform based images respectively.
3. The method of clause 2, further comprising:
evaluating similarity of the plurality of patterns based on distance features of the plurality of vectors.
4. The method of any one of clauses 1-3, wherein the plurality of patterns after Fourier Transform are separated into multiple sets of patterns using a k-means algorithm based on the distance features.
5. The method of any one of clauses 1-4, wherein performing the hierarchical clustering comprises:
performing recursive partitions on the respective set of patterns based on results of the recursively evaluating the features at respective hierarchical levels.
6. The method of any one of clauses 1-5, further comprising performing a cohesion test for evaluating the features, the cohesion test comprising:
evaluating a cohesion degree of the respective set of patterns to obtain an evaluation result; and
determining whether to suspend the recursive partitions according to the evaluation result.
7. The method of clause 6, further comprising:
receiving a user input indicating a parameter associated with evaluating the cohesion degree.
8. The method of any one of clauses 1-7, wherein the image data is in Graphic Database System (GDS) format, Graphic Database System II (GDS II) format, Open Artwork System Interchange Standard (OASIS) format, or Caltech Intermediate Format (CIF).
9. A system for grouping a plurality of patterns extracted from image data, the system comprising:
a controller including circuitry configured to cause the system to perform:
receiving the image data including the plurality of patterns that represent features to be formed on a portion of a wafer;
separating the plurality of patterns after Fourier Transform into multiple sets of patterns; and
performing, on a respective set of patterns, a hierarchical clustering to obtain a plurality of subsets of patterns by recursively evaluating features related to similarity between patterns within the respective set of patterns.
10. The system of clause 9, wherein the circuitry is further configured to cause the system to perform:
performing Fourier Transform on the plurality of patterns to obtain, respectively, a plurality of Fourier Transform based images in a frequency domain; and
obtaining a plurality of vectors based on the plurality of Fourier Transform based images respectively.
11. The system of clause 10, wherein the circuitry is further configured to cause the system to perform:
evaluating similarity of the plurality of patterns based on distance features of the plurality of vectors.
12. The system of any one of clauses 9-11, wherein the plurality of patterns after Fourier Transform are separated into multiple sets of patterns using a k-means algorithm based on the distance features.
13. The system of any one of clauses 9-12, wherein performing the hierarchical clustering comprises:
performing recursive partitions on the respective set of patterns based on results of the recursively evaluating the feature at respective hierarchical levels.
14. The system of any one of clauses 9-13, wherein the circuitry is further configured to cause the system to perform:
performing a cohesion test for evaluating the feature, the cohesion test comprising:
   evaluating a cohesion degree of the respective set of patterns to obtain an evaluation result; and
   determining whether to suspend the recursive partitions according to the evaluation result.
15. The system of clause 14, wherein the circuitry is further configured to cause the system to perform:
receiving a user input indicating a parameter associated with evaluating the cohesion degree.
16. The system of any one of clauses 9-15, wherein the image data is in Graphic Database System (GDS) format, Graphic Database System II (GDS II) format, Open Artwork System Interchange Standard (OASIS) format, or Caltech Intermediate Format (CIF).
17. A non-transitory computer readable medium that stores a set of instructions that is executable by at least one processor of a system to cause the system to perform a method of grouping a plurality of patterns extracted from image data, the method comprising:
receiving the image data including the plurality of patterns that represent features to be formed on a portion of a wafer;
separating the plurality of patterns after Fourier Transform into multiple sets of patterns; and
performing, on a respective set of patterns, a hierarchical clustering to obtain a plurality of subsets of patterns by recursively evaluating features related to similarity between patterns within the respective set of patterns.
18. The non-transitory computer readable medium of clause 17, wherein the set of instructions that is executable by the at least one processor of the computing device to cause the computing device to further perform:
performing Fourier Transform on the plurality of patterns to obtain, respectively, a plurality of Fourier Transform based images in a frequency domain; and
obtaining a plurality of vectors based on the plurality of Fourier Transform based images respectively.
19. The non-transitory computer readable medium of clause 18, wherein the set of instructions that is executable by the at least one processor of the computing device to cause the computing device to further perform:
evaluating similarity of the plurality of patterns based on distance features of the plurality of vectors.
20. The non-transitory computer readable medium of any one of clauses 17-19, wherein the plurality of patterns after Fourier Transform are separated into multiple sets of patterns using a k-means algorithm based on the distance features.
21. The non-transitory computer readable medium of any one of clauses 17-20, wherein performing the hierarchical clustering comprises:
performing recursive partitions on the respective set of patterns based on results of the recursively evaluating the feature at respective hierarchical levels.
22. The non-transitory computer readable medium of any one of clauses 17-21, wherein the set of instructions that is executable by the at least one processor of the computing device to cause the computing device to further perform:
performing a cohesion test for evaluating the feature, the cohesion test comprising:
   evaluating a cohesion degree of the respective set of patterns to obtain an evaluation result; and
   determining whether to suspend the recursive partitions according to the evaluation result.
23. The non-transitory computer readable medium of clause 22, wherein the set of instructions that is executable by the at least one processor of the computing device to cause the computing device to further perform:
receiving a user input indicating a parameter associated with evaluating the cohesion degree.
24. The non-transitory computer readable medium of any one of clauses 17-23, wherein the image data is in Graphic Database System (GDS) format, Graphic Database System II (GDS II) format, Open Artwork System Interchange Standard (OASIS) format, or Caltech Intermediate Format (CIF).
25. A method of grouping a plurality of patterns, the method comprising:
receiving image data including the plurality of patterns that represent features to be formed on a portion of a wafer;
performing a hierarchical clustering on a plurality of frequency domain features transformed from the plurality of patterns respectively, wherein performing the hierarchical clustering comprises recursively partitioning the plurality of frequency domain features by performing:
   receiving a user selection of a parameter; and
   recursively evaluating, based on the parameter, whether to continue to partition corresponding sets of patterns at respective hierarchical levels.
26. The method of clause 25, wherein evaluating whether to continue to partition a set of patterns at a corresponding hierarchical level comprises:
evaluating similarity of patterns within the set of patterns.
27. The method of any of one of clauses 25-26, further comprising:
receiving the user selection of a radius of a test circle;
determining a cohesion degree of the set of patterns, the cohesion degree related to a number of datapoints corresponding to the patterns that are included in the test circle; and
determining whether to continue to partition the set of patterns based on a comparison between the cohesion degree and a predetermined threshold value.
28. The method of any one of clauses 25-27, prior to performing the hierarchical clustering, the method further comprises:
transforming the plurality of patterns into the plurality of frequency domain features; and separating the plurality of frequency domain features into multiple first-level sets of patterns.
29. A system for grouping a plurality of patterns, the system comprising:
a controller including circuitry configured to cause the system to perform:
   receiving image data including the plurality of patterns that represent features to be formed on a portion of a wafer;
   performing a hierarchical clustering on a plurality of frequency domain features transformed from the plurality of patterns respectively, wherein performing the hierarchical clustering comprises recursively partitioning the plurality of frequency domain features by performing:
      receiving a user selection of a parameter; and
      recursively evaluating, based on the parameter, whether to continue to partition corresponding sets of patterns at respective hierarchical levels.
30. The system of clause 29, wherein evaluating whether to continue to partition a set of patterns at a corresponding hierarchical level comprises:
evaluating similarity of patterns within the set of patterns.
31. The system of any of one of clauses 29-30, wherein the circuitry is further configured to cause the system to perform:
receiving the user selection of a radius of a test circle;
determining a cohesion degree of the set of patterns, the cohesion degree related to a number of datapoints corresponding to the patterns that are included in the test circle; and
determining whether to continue to partition the set of patterns based on a comparison between the cohesion degree and a predetermined threshold value.
32. The system of any one of clauses 29-31, wherein the circuitry is further configured to cause the system to perform:
prior to performing the hierarchical clustering,
   transforming the plurality of patterns into the plurality of frequency domain features; and
   separating the plurality of frequency domain features into multiple first-level sets of patterns.
33. A non-transitory computer readable medium that stores a set of instructions that is executable by at least one processor of a system to cause the system to perform a method of grouping a plurality of patterns, the method comprising:
receiving image data including the plurality of patterns that represent features to be formed on a portion of a wafer;
performing a hierarchical clustering on a plurality of frequency domain features transformed from the plurality of patterns respectively, wherein performing the hierarchical clustering comprises recursively partitioning the plurality of frequency domain features by performing:
   receiving a user selection of a parameter; and
   recursively evaluating, based on the parameter, whether to continue to partition corresponding sets of patterns at respective hierarchical levels.
34. The non-transitory computer readable medium of clause 33, wherein evaluating whether to continue to partition a set of patterns at a corresponding hierarchical level comprises:
evaluating similarity of patterns within the set of patterns.
35. The non-transitory computer readable medium of any of one of clauses 33-34, wherein the set of instructions that is executable by the at least one processor of the computing device to cause the computing device to further perform:
receiving the user selection of a radius of a test circle;
determining a cohesion degree of the set of patterns, the cohesion degree related to a number of datapoints corresponding to the patterns that are included in the test circle; and
determining whether to continue to partition the set of patterns based on a comparison between the cohesion degree and a predetermined threshold value.
36. The non-transitory computer readable medium of any of one of clauses 33-35, prior to performing the hierarchical clustering, wherein the set of instructions that is executable by the at least one processor of the computing device to cause the computing device to further perform:
transforming the plurality of patterns into the plurality of frequency domain features; and
separating the plurality of frequency domain features into multiple first-level sets of patterns.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A system for grouping a plurality of patterns extracted from image data, the system comprising:
a controller including circuitry configured to cause the system to perform:
receiving the image data including the plurality of patterns that represent features to be formed on a portion of a wafer;
separating the plurality of patterns after Fourier Transform into multiple sets of patterns; and
performing, on a respective set of patterns, a hierarchical clustering to obtain a plurality of subsets of patterns by recursively evaluating features related to similarity between patterns within the respective set of patterns.

2. The system of claim 1, wherein the circuitry is further configured to cause the system to perform:
performing Fourier Transform on the plurality of patterns to obtain, respectively, a plurality of Fourier Transform based images in a frequency domain; and
obtaining a plurality of vectors based on the plurality of Fourier Transform based images respectively.

3. The system of claim 2, wherein the circuitry is further configured to cause the system to perform:
evaluating similarity of the plurality of patterns based on distance features of the plurality of vectors.

4. The system of claim 1, wherein the plurality of patterns after Fourier Transform are separated into multiple sets of patterns using a k-means algorithm based on the distance features.

5. The system of claim 1, wherein performing the hierarchical clustering comprises:
performing recursive partitions on the respective set of patterns based on results of the recursively evaluating the feature at respective hierarchical levels.

6. The system of claim 5, wherein the circuitry is further configured to cause the system to perform:
performing a cohesion test for evaluating the feature, the cohesion test comprising:
evaluating a cohesion degree of the respective set of patterns to obtain an evaluation result; and
determining whether to suspend the recursive partitions according to the evaluation result.

7. The system of claim 6, wherein the circuitry is further configured to cause the system to perform:
receiving a user input indicating a parameter associated with evaluating the cohesion degree.

8. The system of claim 1, wherein the image data is in Graphic Database System (GDS) format, Graphic Database System II (GDS II) format, Open Artwork System Interchange Standard (OASIS) format, or Caltech Intermediate Format (CIF).

9. A non-transitory computer readable medium that stores a set of instructions that is executable by at least one processor of a system to cause the system to perform a method of grouping a plurality of patterns extracted from image data, the method comprising:
receiving the image data including the plurality of patterns that represent features to be formed on a portion of a wafer;
separating the plurality of patterns after Fourier Transform into multiple sets of patterns; and
performing, on a respective set of patterns, a hierarchical clustering to obtain a plurality of subsets of patterns by recursively evaluating features related to similarity between patterns within the respective set of patterns.

10. The non-transitory computer readable medium of claim 9, wherein the set of instructions that is executable by the at least one processor of the system to cause the system to further perform:
performing Fourier Transform on the plurality of patterns to obtain, respectively, a plurality of Fourier Transform based images in a frequency domain; and
obtaining a plurality of vectors based on the plurality of Fourier Transform based images respectively.

11. The non-transitory computer readable medium of claim 10, wherein the set of instructions that is executable by the at least one processor of the system to cause the system to further perform:
evaluating similarity of the plurality of patterns based on distance features of the plurality of vectors.

12. The non-transitory computer readable medium of claim 9, wherein the plurality of patterns after Fourier Transform are separated into multiple sets of patterns using a k-means algorithm based on the distance features.

13. The non-transitory computer readable medium of claim 9, wherein performing the hierarchical clustering comprises:
performing recursive partitions on the respective set of patterns based on results of the recursively evaluating the feature at respective hierarchical levels.

14. The non-transitory computer readable medium of claim 13, wherein the set of instructions that is executable by the at least one processor of the system to cause the system to further perform:
performing a cohesion test for evaluating the feature, the cohesion test comprising:
evaluating a cohesion degree of the respective set of patterns to obtain an evaluation result; and
determining whether to suspend the recursive partitions according to the evaluation result.

15. The non-transitory computer readable medium of claim 14, wherein the set of instructions that is executable by the at least one processor of the system to cause the system to further perform:
receiving a user input indicating a parameter associated with evaluating the cohesion degree.

16. A method of grouping a plurality of patterns extracted from image data, the method comprising:
receiving the image data including the plurality of patterns that represent features to be formed on a portion of a wafer;
separating the plurality of patterns after Fourier Transform into multiple sets of patterns; and
performing, on a respective set of patterns, a hierarchical clustering to obtain a plurality of subsets of patterns by recursively evaluating features related to similarity between patterns within the respective set of patterns.

17. The method of claim 16, further comprising:
performing Fourier Transform on the plurality of patterns to obtain, respectively, a plurality of Fourier Transform based images in a frequency domain; and
obtaining a plurality of vectors based on the plurality of Fourier Transform based images respectively.

18. The method of claim 17, further comprising:
evaluating similarity of the plurality of patterns based on distance features of the plurality of vectors.

19. The method of claim 16, wherein the plurality of patterns after Fourier Transform are separated into multiple sets of patterns using a k-means algorithm based on the distance features.

20. The method of claim 16, wherein performing the hierarchical clustering comprises:
performing recursive partitions on the respective set of patterns based on results of the recursively evaluating the feature at respective hierarchical levels.
